(19) United States
(12) Patent Application Publication
(10) Pub. No.: US 2008/0291723 A1
(43) Pub. Date: Nov. 27, 2008

(54) SOURCE BIASING OF NOR-TYPE FLASH ARRAY WITH DYNAMICALLY VARIABLE SOURCE RESISTANCE

(76) Inventors: Daniel C. Wang, San Jose, CA (US); Yue-Song He, San Jose, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/752,711

(22) Filed: May 23, 2007

(51) Int. Cl. G11C 11/34; H01L 29/788

(52) U.S. Cl. 365/185.3; 257/315; 438/257; 257/E29.3

(57) ABSTRACT

A dynamically variable source resistance is provided for each sector of a NOR-type Flash memory device. The variable source resistance of a given sector is set to a relatively low value (i.e., close to zero) during read operations. The variable source resistance is set to a relatively high impedance value (i.e., close to being an open circuit) during flash erase operations. The variable source resistance is set to a first intermediate resistance value at least during soft-programming where the first intermediate resistance value is one that raises V_{S} and thus drives V_{GS} below local threshold even for over-erased transistors of the sector that have a V_{Goff} de-assertion voltage applied to their control gates for purpose of turning those transistors off. In one embodiment, the variable source resistance is set to a second intermediate resistance value during a testing mode that tests the extent to which the corresponding sector has been over-erased. The results of the testing mode are then used to intelligently optimize the number of transistors that are simultaneously soft-programmed in that sector during each Vₜ compaction cycle.

### FIELD OF DISCLOSURE

The present disclosure of invention relates generally to NOR-type Flash memory arrays and more specifically to methods of biasing the commonly connected source regions of each sector of a NOR-type Flash memory during read, write (program), and erase (blanket clear) operations.

### DESCRIPTION OF RELATED ART

NOR-type Flash memory arrays are well known. So is the problem of biasing the commonly connected source regions of such devices. Examples of patents that deal with the problem include: U.S. Pat. No. 6,570,787 (Wang et al 2003) and U.S. Pat. No. 6,852,594 (Wang et al 2005).

Briefly, NOR-type Flash memory arrays are referred to as such because pairs of adjacent floating gate transistors share a common source region in order to provide a compact layout. Typically, each floating gate transistor comprises a source region, a drain region, a channel region (disposed between the source and drain and also disposed above a substrate well), a tunnel insulator layer disposed over the channel region, a floating gate (FG) disposed over the tunnel insulator, a second insulator(s) layer (i.e. ONO) disposed over the FG and a control gate (CG) disposed over the second insulator(s) layer.

Flash memory arrays are generally erased as large blocks of many transistors that are cleared simultaneously rather than as one cell at a time (i.e., one bit at a time if data storage per cell is not of the multi-bit kind). During block-wide erase, the source and drain of each transistor are typically disconnected (i.e. floating or tied to a very high impedance) while an appropriate erase voltage is applied across the control gate (CG) and the substrate well (i.e., P-well) of each transistor. A common erase mode configuration applies approximately −9 Volts to the control gate and approximately +9V to the substrate well so as to thereby induce tunneling (i.e. Fowler-Nordheim tunneling) of electrons from the floating gate (FG), through the tunnel insulator layer (i.e., tunnel oxide) and into the channel region or other parts of the substrate. Such positive charging of the floating gates (FG's) decreases a threshold voltage (Vₜ) above which the control gate (CG) must be later charged to in order to render the corresponding transistor conductive (e.g., turned ON) during selective read operations. The intent of a selective read operation is to pass a measurable drain-to-source current (I_{DS}) through the transistor in response to the turn on voltage, V_{Gon} applied to its control gate and the read-mode voltage, V_{Dread} applied to its drain by way of a resistive bit line. If binary data storage is employed, then a relatively large I_{DS} will flow during reading and this will typically indicate the cell is still erased (i.e., to thereby represent a binary 1 bit for example). On the other hand, if a substantially smaller or no measurable I_{DS} current flows, this will typically indicate the cell has been programmed (i.e., to thereby represent a binary 0 bit for example). If multi-bit data storage per cell is employed, then different ranges of I_{DS} will be allocated to respectively represent 00, 01, 10 and 11 for example.

When large blocks or sectors of floating gate transistors are flash erased, an associated problem known as over-erasure often occurs. The threshold voltages (Vₜ) of some flash transistors are driven abnormally low, even into the negative territory. Such abnormally low or negative Vₜ's make it difficult to stop current from leaking through the over-erased transistors even though a turn-off voltage such as V_{Goff}=0V is applied. A process known as soft-programming (or Vₜ compaction) is typically used to mitigate the over-erase problem. The purpose of soft-programming is nudge the abnormally low Vₜ's of the over-erased transistors slightly higher but not to high so that they are turned off irrespective of what nominal addressing voltage (V_{Gon}) is applied to their control gates.

During the soft-programming (Vₜ compaction) process, voltages will be applied to one over-erased transistor for repairing it by shifting its programmable Vₜ slightly higher. However, adjacent and still not-yet-repaired transistors (of the same sector) may continue to leak large amounts leakage current by way of the same or other bit lines. This leakage current pulls down an output voltage of an on-chip charge pump and interferes with the circuit's ability to soft-program more than one over-erased transistor at a time. In turn, the inability to soft-program many transistors at once limits the number of transistors that can be placed in a flash-erasable sector and thus limits the speed at which large amounts of new data can be written into a flash memory chip.

One elegant solution is to employ light doping of transistor source regions so as to thereby limit excess column leakage and to simultaneously tackle a short channel problem. The above cited U.S. Pat. No. 6,852,594 (Wang et al 2005), whose disclosure is incorporated herein by reference, provides details regarding such a solution and thus its details will not be repeated here. Light doping of transistor sources is not without its drawbacks however. Lightly doped sources tend to decrease current flow (IDS) during read operation due to the resistance of the light doping in the source region. Practitioners are therefore caught in a Hobson's choice dilemma between having to accept large leakage currents during soft programming if they don't employ light source doping or having to accept reduced read currents if they do employ light source doping. Reduction of read currents causes the memory to be more susceptible to noise problems.

### SUMMARY

A dynamically variable source resistance is provided for each sector of a Flash memory device. The variable source resistance of a given sector is set to a relatively low value (i.e., close to zero) during read operations. The variable source resistance is set to a relatively high impedance value (i.e., close to being an open circuit) during flash erase operations. The variable source resistance is set to a first intermediate resistance value at least during soft-programming where the first intermediate resistance value is one that raises V_{S} and thus drives V_{GS} below local threshold for transistors of the sector that have a V_{G}off de-assertion voltage applied to their control gates for purpose of turning those transistors off.

In one embodiment, the variable source resistance is set to a second intermediate resistance value during a testing mode that tests the extent to which the corresponding sector has been over-erased. The results of the testing mode are then used to intelligently optimize the number of transistors that are simultaneously soft-programmed in that sector during each Vₜ compaction cycle.

Other aspects of the disclosure will become apparent from the below detailed description.

### BRIEF DESCRIPTION OF THE DRAWINGS

The below detailed description section makes reference to the accompanying drawings, in which:

FIG. 1A is a schematic cross sectional side view of three floating gate transistors in a conventional NOR-array column;

FIG. 1B is a circuit schematic showing a plurality of Flash-erasable floating gate transistors in a conventional NOR-array column and a sector switch that is used for binary control of the common source state;

FIG. 1C is a schematic diagram of a floating gate transistor during an FN tunneling based, flash erase operation;

FIG. 1D is a schematic diagram showing two floating gate transistors that are tied to a common drain line during a hot carrier programming operation;

FIG. 1E is a schematic diagram of a floating gate transistor during a data read operation;

FIG. 2A is a circuit schematic showing a plurality of Flash-erasable floating gate transistors in a NOR-array device that includes a variable resistance and first means for dynamically controlling the common source state in accordance with the disclosure;

FIG. 2B is a circuit schematic showing a plurality of Flash-erasable floating gate transistors in a NOR-array device that includes a discretely variable resistance network and second means for dynamically controlling the common source state in accordance with the disclosure;

FIG. 2C is a circuit schematic of a Flash-erasable memory sector that includes a variable sector resistance corresponding for example to the analog variable resistance of FIG. 2A or the digital variable resistance of FIG. 2B;

FIG. 2D is a schematic diagram of two floating gate transistors during a hot carrier programming operation wherein a dynamically variable resistance is interposed between the common source plane and ground and a V_{Goff} voltage of 0V is applied to the control gate of a still over-erased one of the transistors;

FIG. 2E is a schematic diagram of a floating gate transistor during a data read operation wherein a dynamically variable resistance (driven to its R₀ setting) is interposed between the common source plane and ground;

FIG. 3A is a block diagram of a monolithic integrated circuit (IC) chip comprising a plurality of Flash-erasable, nonvolatile memory sectors, each having a corresponding variable resistance means for dynamic control of the common source state of that sector during respective read, erase, soft-programming and hard-programming of the sector in accordance with the disclosure; and

FIG. 3B is a flow chart of a method of operating the IC of FIG. 3A.

### DETAILED DESCRIPTION

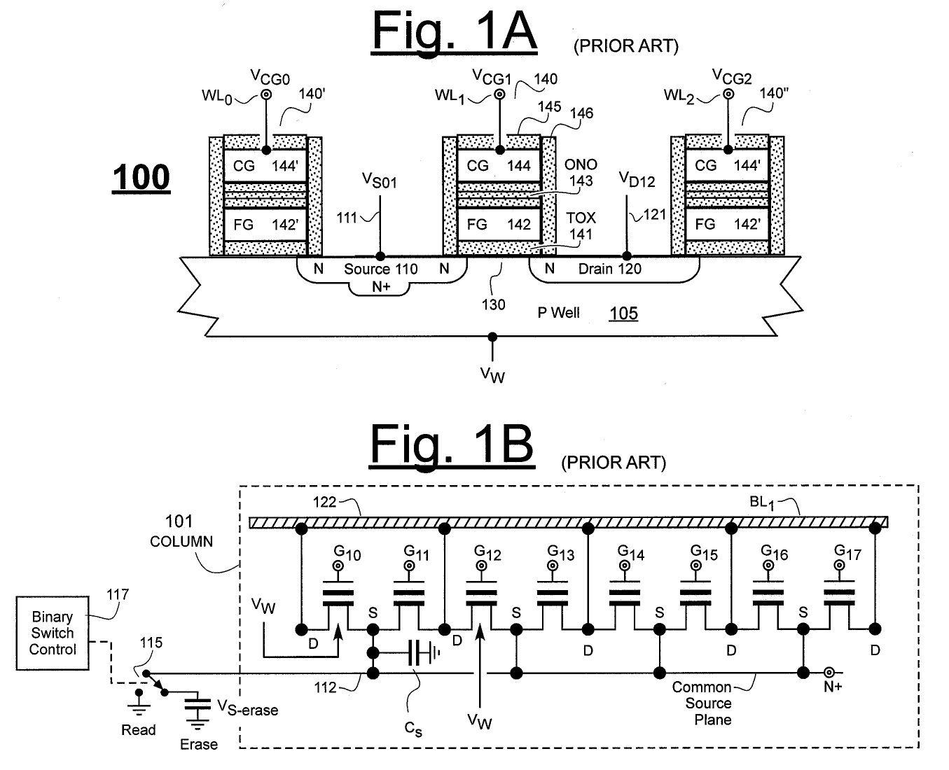

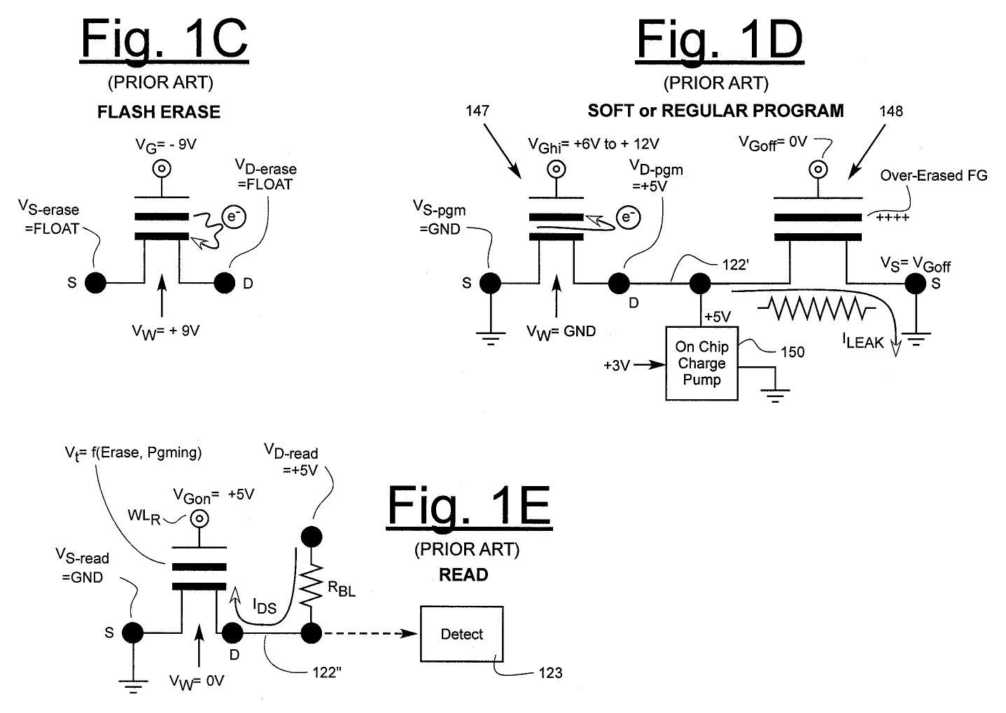

FIG. 1A is a schematic cross sectional side view showing three floating gate transistors in a NOR-array column of a conventional Flash memory device 100. The central gate stack 140 (coupled to word line WL₁) defines part of a first nonvolatile memory cell that includes an N-type source region 110, an N-type drain region 120, and a P-type channel region 130. The source and drain regions, 110 and 120, are implanted in a P-well 105 that is contiguous with the channel region 130. The source, drain, channel and well regions may be integrally formed in a monolithic semiconductor substrate (i.e., monocrystalline silicon) by way of various well known doping techniques such as ion implant.

Source region 110 is in communication with a common source line (112 of FIG. 1B) by way of a source contact 111, while drain region 120 is in communication with a column bit line (122 of FIG. 1B) by way of a drain contact 121. Source contact 111 and drain contact 121 may be separated from the stacked gate structure 140 by way of one or more insulators, including sidewall insulator layers 146.

The illustrated gate structure 140 includes a tunnel oxide region 141 that separates a conductive floating gate 142 (i.e., polysilicon) from the channel region 130 by a sufficiently small distance so as to enable electron tunneling through the lower gate insulator 141. A thicker dielectric region 143 (typically of an Oxide/Nitride/Oxide configuration, or ONO) separates the floating gate 142 from a conductive control gate 144 (i.e., polysilicon). Although not fully shown, control gate (CG) 144 is in communication with a first word line (WL₁) that extends orthogonally relative to the plane of the paper and that generally receives a cell-addressing signal indicating whether that particular cell (140) is to be read or programmed. In the FIGS. 1A and 1B, a circle-in-a-circle symbol is used to denote a line extending orthogonally relative to the plane of the drawing. A capping dielectric region 145 joins with sidewall spacers 146 to provide isolation for gate structure 140 so that charge can be efficiently trapped in its floating gate (FG) 142. As seen in FIG. 1A, source region 110 is shared by a second gate stack 140′ (WL₀) while drain region 120 is shared by a third gate stack 140″ (WL₂). This allows for a compact layout that is typically referred to as a NOR array configuration.

FIG. 1B provides a circuit schematic view of a NOR-type memory column 101 that perhaps better illustrates the layout compaction that may be achieved by sharing source or drain regions between pairs of immediately adjacent transistors. FIG. 1B shows a metal bit line 122 crossing above the active device layer and connecting with the shared drain nodes (D). Source regions of adjacent columns (only one shown in FIG. 1B) may couple to one another through N+ extensions (see FIG. 1A) that run through the substrate in an extension direction orthogonal to the plane of the paper. Parallel ones of such source N+ extensions may be periodically cross connect with metal source lines so as to form a common coupling plane for all source regions of a given memory sector. A typical memory sector may contain a matrix of about 4,096 memory cells. The common sources coupling plane is represented in FIG. 1B as 112 and is understood to have an inherent parasitic capacitance, C_{S} associated therewith. FIG. 1B further shows that the common source plane 112 of a given sector is conventionally connected to a binary sector switch 115 that is operated by a corresponding binary sector switch control circuit 117. Of importance, during read operations, the binary switch 115 connects the common source plane 112 of the given sector to ground (or another corresponding reference voltage) while during erase operations, the binary switch 115 effectively disconnects the common source plane 112 and allows it to float to its own, sought after voltage level, V_{S-erase}. The value of V_{S-erase} is typically determined by an electric field created during flash erase operations between the well contact voltage, V_{W} and an applied control gate voltage (V_{G-erase}).

Referring to FIG. 1C, a number of different techniques may be employed for inducing Fowler-Nordheim tunneling during a flash erase operation. In one embodiment, each of the source and drain nodes is allowed to float to its own self-sought voltage level. In FIG. 1B the self-sought voltage level of the floating source plane 112 is denoted as V_{S-erase}. and this voltage appears across the parasitic capacitance C_{S} of the common source plane. The control gate is biased to a negative voltage of relatively high value (e.g., V_{G}=−9V), and the P-well is biased a positive voltage of relatively high value (e.g., V_{W}=+9V) so as to thereby establish an even larger voltage drop between the CG and the substrate (e.g., 18V). As a consequence of the relatively large electric field that is established, negative charge carriers (i.e., free electrons) are induced to tunnel out of the floating gate (FG) and through the tunnel oxide (TOX 141) for neutralization in the P-well (105). The process is typically referred to as Fowler-Nordheim tunneling. Other forms of charge removal from the FG may be additionally or alternatively used.

The floating gate (FG) of each memory cell in the sector becomes more positively charged as a result of localized removal of some of its electrons. As is well known in the art, the level of charge retained in the floating gate (FG) affects a threshold level, Vₜ of the corresponding transistor. During read operations (FIG. 1E), the effective V_{t-READ} level of the transistor determines how strongly the transistor becomes conductive or not when respective gate voltages of +5V and 0V (for example) are applied to the gate of that transistor. In one class of embodiments, an optimum threshold voltage for an erased cell (if not over-erased) is nominally about 2 volts. If a memory cell is optimally erased into this nominal state (V_{t-READ}=V_{tNominal}=+2V), then when the associated word line is asserted at a corresponding assertion level (i.e. V_{Gon}=+5V), then a substantial magnitude of current (I_{DS}) will flow through the bit line. This event is generally used to represent a digital “1” state. Conversely, if the associated word line is de-asserted at a corresponding de-assertion level (i.e. V_{Goff}=+0V) during read mode, then a relatively small or unmeasurable magnitude of current (I_{DS}) will flow through the bit line. This latter event is usually used to represent a digital “0” state.

As indicated, electron tunneling is a localized phenomenon. Due to randomness of tunneling effects, fabrication variations and/or other locality dependent phenomenon, not all transistors will have a same threshold level, Vₜ after a Flash erase operation is carried out. If the post-erase Vₜ distribution is too wide relative to the nominal threshold voltage (e.g., V_{tNominal}=+2V), some of the cells can have very low, below nominal or even negative Vₜ's, which makes it difficult later to turn them off with application of the chip-wide nominal de-assertion level (i.e. V_{Goff}=+0V). FIG. 1D shows one transistor 148 having a relatively low (subnominal) or negative threshold level, Vₜ, this being represented by plus signs next to its floating gate (FG). When erasure pushes one or more transistors too deep towards the negative Vₜ range, such over-erasure can lead to subsequent errors when trying to read a properly programmed first cell (“0” state) that happens to share a bit line 122 with an over-erased and thus current-leaking second cell, since the current of the leaking second cell (even though the second cell is not addressed) may result in detection of a “1” state on the bit line rather than the low or no current “0” state of the addressed cell. Excessive over-erasure of too many cells may also lead to problems when individualized programming of adjacent cells is attempted or when “soft-programming” of plural cells at once is attempted.

Over-erasure can be cured by a conventional technique known as “soft-programming”. The extent of over-erasure of individuals cells is determined, and then a partial programming process is used to nudge the subnominal threshold levels, Vₜ, of those over-erased cells closer to the nominal Vₜ, for example from a first threshold value of V_{tSub}=−1V to a second of V_{tNominal}=+2V. The soft-programming process will be easier to understand if the regular or hard programming process is described first, even though soft-programming is carried out first and regular programming is carried out afterwards. For this explanation, assume that flash erasure resulted in the ideal condition where the post-erasure threshold voltage (Vₜ) of all transistors in the sector is the nominal Vₜ=+2V. Under this assumption, when the chip-wide nominal de-assertion level (i.e. V_{Goff}=+0V) is applied to the gate of transistor 148 (FIG. 1D), the applied V_{Goff} level will be well below local threshold for transistor 148. As a result, transistor 148 will be substantially turned off and essentially no leakage current will flow. Thus it can be assumed that I_{LEAK} is approximately zero in this ideal situation and the presence of transistor 148 in the circuit can be ignored.

Still referring to FIG. 1D, a hot-carrier programming operation (hot carrier injection, or HCI) may be carried out as follows. A relatively high positive voltage (e.g., V_{Ghi}=V_{Ghard}=+9V to +12 volts) may be applied to the control gate (144) of transistor 147. A relatively high, but usually lower, positive voltage (e.g., V_{D}=+5V to +6 volts) may be applied to the drain region (120) of transistor 147. The common source plane (112) of the sector is held close to ground. Since transistor 147 also has a Vₜ of about 2V, it will be turned heavily on as a result of the high gate voltage, V_{Ghi}. Electrons will be ballistically accelerated from the source region (110) of transistor 147 to its drain region (120) due to the electric field present between source and drain. Some of the energetic electrons will have sufficient kinetic energy to cross through the gate oxide (141) and come to be injected into and trapped on the floating gate (142). If this is done for a sufficiently long time, charge accumulates on the floating gate (142), causing it to become negatively charged, and eventually the threshold voltage of transistor rises substantially above the nominal +2V to say a supernominal value of about +4.5V or higher. As a result of this, the transistor is hard programmed to be turned off (substantially nonconductive) even when its word line is asserted with the nominal turn on voltage (at say a V_{Gon} of about +4.5V to +5V).

Now that this understood, let us return to a real world case where after flash erasure, each of transistors 147 and 148 is over-erased to have a threshold voltage of say Vₜ=−0.1V. As a consequence, when the chip's de-assertion level (i.e. V_{Goff}=+0V) is applied to the control gate of the transistor while the drain is at about V_{D}=+5V, a not insubstantial amount of leakage current (I_{LEAK}) will flow through the transistor (i.e., through 148). Although leakage current (I_{LEAK}) through a single transistor may not be that large, it should be recalled that all transistors of a given bit line (i.e., BL 122 of FIG. 1B) have their drains connected together via the bit line and thus their leakage currents add up. Moreover it is to be appreciated that the V_{D}=+5V or higher voltage that is asserted on the bit line 122′ is typically generated by an on-chip charge pump 150. For example, the external supply of the integrated circuit chip may supply only +3V. The bit line charge pump 150 pumps it up to the desired +5V level. (Other on-chip charge pumps (not shown) similarly produce the various other on-chip voltages: +9V, −9V, etc.) The bit line charge pump 150 has the ability to supply only so much current before its output voltage begins to drop below the desired level. Thus if the bit line charge pump 150 is simultaneously connected to too many bit lines each having too many, heavily over-erased transistors, the charge pump will not be able to maintain a sufficiently high voltage (e.g., V_{D}=+5V to +6 volts) for desired programming operations. Thus, it is conventional to select only a few bit lines at a time (i.e., 2 to 5) for correction by way of soft-programming. The exact number of selected bit lines may vary from application to application and it is normally fixed by the designers of the chip in light of expected manufacturing variations and expected in-field conditions. Although not shown, it is to be understood that each bit line like 122′ has a binary switch coupling the bit line to charge pump 150. A conventional design will fix the number, N of bit lines that are simultaneously coupled selectively to the charge pump 150 during a soft-programming operation. The reason for this is to limit the total amount of leakage current (I_{Leak}) that the charge pump 150 has to support at any one time. If I_{Leak} per turned-on bit line is relatively high in a given design, then N, the fixed number of selectively turned-on bit lines has to be set to a relatively small number in order to preserve the drain programming voltage (V_{D-pgm}) desired on lines 122′.

In a conventional soft programming process, a relatively high, but not as high as regular programming voltage (i.e., V_{Gsoft}≦+8V but greater than about +5V) is applied to the gates of one or a few cells simultaneously for a predetermined time so as to transfer enough charge via hot carrier injection so as to nudge the Vₜ of the addressed transistors towards a desired nominal value (i.e., +2V). Alternatively or additionally the soft program voltage may be supplied as a series of short pulses at the lower programming voltage (i.e., V_{Gsoft}=+8V). Soft-programming works to narrow the distribution of threshold voltages among the memory cells, so that the threshold voltages more closely correspond to the desired nominal threshold voltage for all erased cells. Soft-programming is thus often also referred to as threshold compaction.

Stated otherwise, after a flash erase, the step of soft-programming includes applying a soft-programming voltage (V_{Ghi}=V_{Gsoft}) to the control gates of over-erased floating gate transistors that are being soft-programmed where the soft-programming voltage is less than a hard-programming voltage (V_{Ghi}=V_{Ghard}) applied to the control gates of floating gate transistors that are being hard-programmed. The soft-programming operation shifts a local and subnominal threshold voltage of an over-erased transistor that is being soft-programmed towards an intermediate or nominal threshold voltage (e.g., V_{tNominal}=+2V) that allows the transistor to be turned off when a nominal de-assertion voltage (e.g., V_{Goff}=0V) is applied to the control gate of the soft-programmed transistor and to be turned on when a nominal assertion voltage (e.g., V_{Gon}=+4.5V) is applied to the control gate of the soft-programmed transistor. Contrastingly, a hard-programming operation shifts a local threshold voltage of a transistor that is being hard-programmed to an above-nominal threshold voltage (e.g., V_{tSuper}=+5V) that prevents the transistor from being turned on when a nominal assertion voltage (e.g., V_{Gon}=+4.5V) is applied to the control gate of the hard-programmed transistor.

A problem is emerging in the field of flash memory devices. Memory densities are heading toward higher numbers. As a result it is desirable to increase the number of floating gate transistors per sector from the conventional value of about 4 K or less to much higher values on the order of say, 0.5 Mega transistors per sector. After a sector is flash erased (i.e., FIG. 1C), it is desirable to complete the soft-programming process (i.e., FIG. 1D) as quickly as possible so that operations may then proceed to regular programming (i.e., FIG. 1D again but with 148 not leaking anymore) and to subsequent reading (i.e., FIG. 1E) of addressed cells that have been properly erased, and then optionally soft-programmed and/or then optionally hard-programmed. However, excessive cumulative leakage by plural transistors may limit the number of cells that can soft-programmed at the same time in a given sector because the number, N of bit lines that can be simultaneously driven to the desired V_{D-pgm} level is limited to a small number. This in turn may limit the speed at which soft-programming of the entire sector completes and the sector thus becomes ready for hard-programming and subsequent reading of the data stored in the erased-and-rewritten-to sector. In general, it is desirable to minimize time consumed for flash erasing and time consumed for soft-programming as much as possible so that sector re-write time is thereby minimized.

Referring to FIG. 1E, and for purpose of completeness, the read operation is briefly described. As already mentioned, hard-programming causes a sufficient amount of negative charge to become trapped in the floating gate (142) so as to substantially increase the threshold voltage of the transistor and thus cause the transistor to remain turned off (essentially not conducting) when a chip-wide nominal turn on voltage V_{Gon} is asserted onto the word line (WL_{R}) of that transistor during a read operation. A current flow detector 123 connects to the bit line 122″ of the device to determine how much current (I_{DS}) flows when V_{Gon} is asserted. If a substantial amount of current is not seen to flow through the bit line, that state is generally used to represent a digital “0” state. On the other hand, if the detector 123 senses a current flow above a predetermined threshold, that state is generally used to represent a digital “1” state. In one class of embodiments, detector 123 is a voltage detector that senses a voltage drop developed across a bit line resistance, R_{BL}.

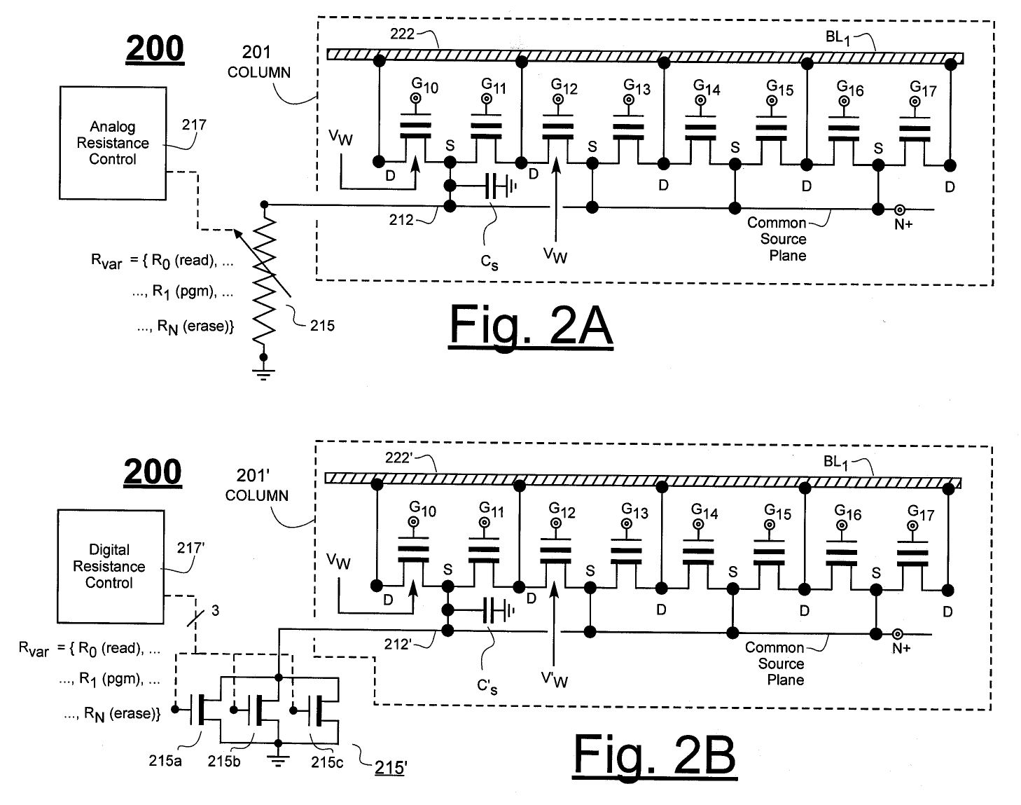

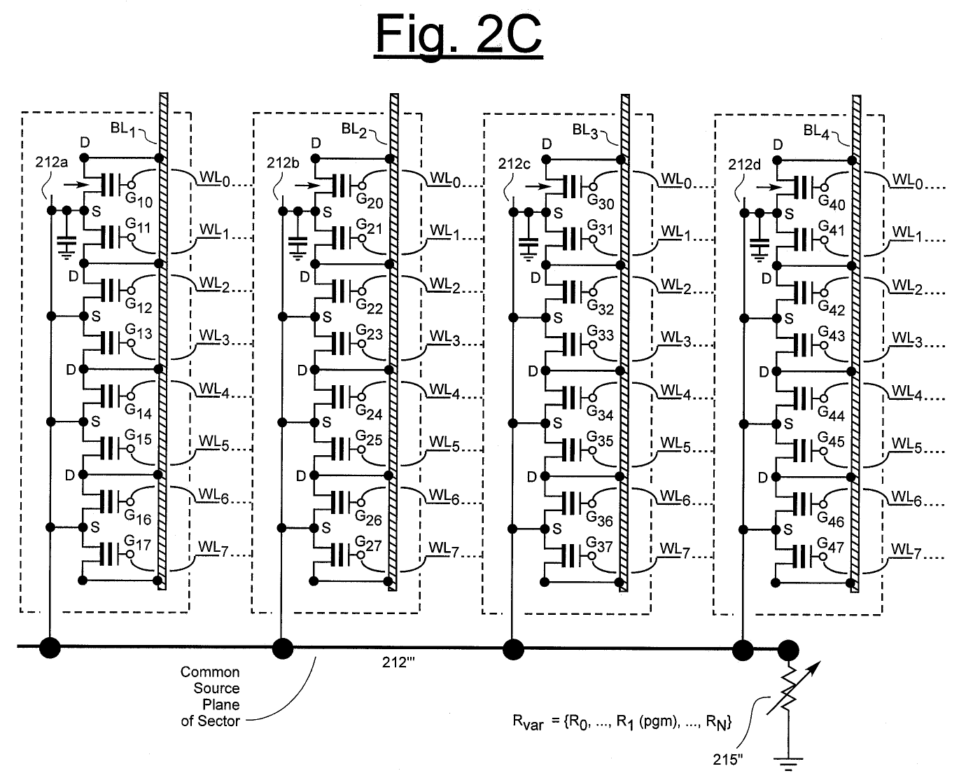

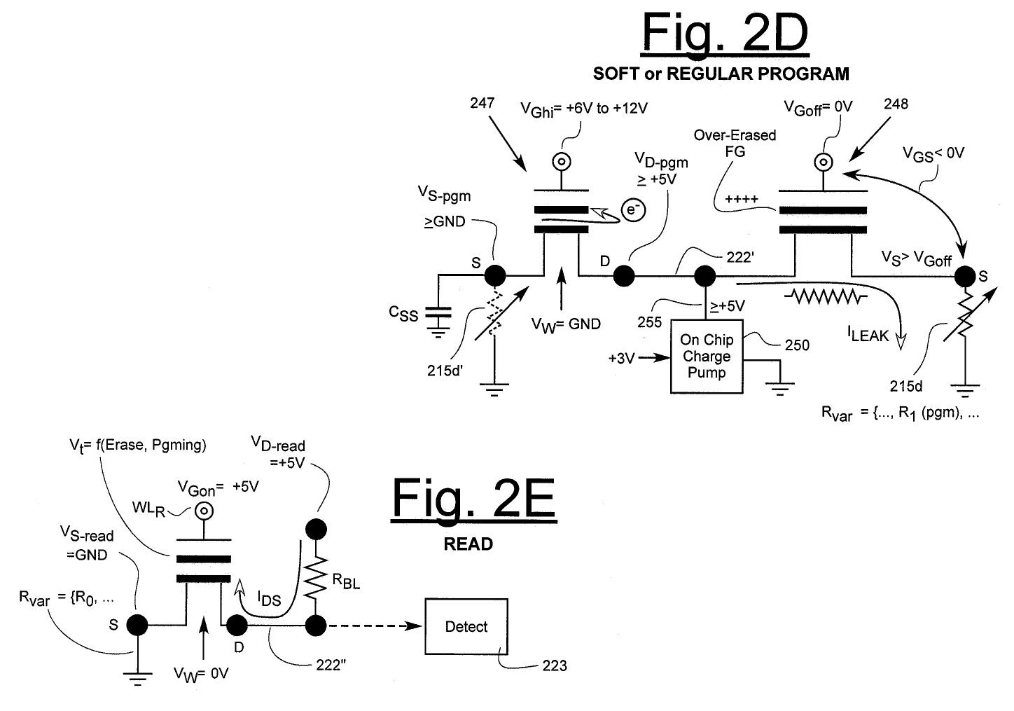

With that as background, reference is made to FIG. 2A. FIG. 2A is a schematic circuit diagram of a first flash memory device 200 in accordance with the present disclosure of invention. Like reference symbols and numbers in the “200” century series are used for elements of FIG. 2A which correspond to but are not necessarily the same as the elements represented by similar symbols and reference numbers of the “100” series in FIG. 1B. As such, a repeated description of most of the elements found in FIG. 2A is not needed here. Of importance, rather than having a binary-only switch such as 115 of FIG. 1B for controlling the state of the common source plane 212, the memory device 200 of FIG. 2A includes a first variable resistance 215 interposed between the corresponding common source plane 212 of column 201 and ground (or another equivalent reference voltage rail) and a control means for dynamically switching the resistance 215 at least to three different values. In one embodiment, the variable resistance 215 (Rᵥₐᵣ) is controlled by an analog control unit 217 so as to provide at least three, dynamically selectable resistance settings, R₀, R₁ and R_{N}. The analog control unit 217 may include a digital-to-analog converter (DAC, not shown) for converting received digital command signals into corresponding analog control signals that are applied to the variable resistance 215. In one embodiment, the first resistance setting, R₀, corresponds to data read operations and constitutes a lowest resistance value for Rᵥₐᵣ so as to thereby couple the common source plane 212 to ground (or another equivalent reference voltage rail) with minimal resistance approximating a shorted connection to ground (or other).

In the same one or another embodiment, the third resistance setting, R_{N}, corresponds to a flash erase operation and constitutes a highest resistance value for Rᵥₐᵣ so as to thereby substantially decouple the common source plane 212 from ground (or another equivalent reference voltage rail) and thus allow the common source plane 212 to essentially float.

In the same one or another embodiment, the second resistance setting, R₁, corresponds to at least one of a soft-programming and hard-programming operation and constitutes an intermediate resistance value for Rᵥₐᵣ so as to thereby control the voltage of the common source plane 212 relative to ground (or to another equivalent reference voltage rail) for a given number N of turned on bit lines and to thus limit the amount of current drained from a programming power source (e.g., 250 of FIG. 2D) during the corresponding programming operations. If desired, the value of the second resistance setting, R₁, may be made a function of the number, N of bit lines whose floating gate transistors are being soft-programmed so as to thereby establish a desired source plane voltage Vs sufficient to keep the over-erased other transistors (248) sufficiently turned off so as not to overtax the on-chip charge pump (e.g., 250 of FIG. 2D).

FIG. 2B is a schematic circuit diagram of a second flash memory device 200′ in accordance with the present disclosure of invention. Like reference symbols and numbers in the primed “200” century series are used for elements of FIG. 2B which correspond to but are not necessarily the same as the elements represented by similar unprimed reference numbers in FIG. 2A. As such, a repeated description of most of the elements found in FIG. 2B is not needed here. The difference in FIG. 2B is that the dynamically variable resistance means 215′ is comprised of a plurality of independently and digitally activatable transistors, 215a, 215b and 215c. In an alternate embodiment, the number of transistors used to define Rᵥₐᵣ 215′ could have been two or more than three. Use of three digitally activatable transistors, 215a-215c, allows for eight dynamically selectable resistance states including one where all three of transistors, 215a-215c are turned off (so as to be substantially nonconductive) and including a second state where all three of transistors, 215a-215c are turned on (so as to each be in a saturated conductive state). In one embodiment, the channel widths of the digitally activatable transistors, 215a, 215b and 215c may be respective organized as ×1, ×2 and ×4 so as to thereby provided for a binary weighted selection of cumulative, turned on channel widths in the range ×0 to ×7 where ×1 (times one) represents the current carrying capacity of the transistor with the smallest channel width. Other weighted distributions of channel widths may alternatively be used.

As in the case of FIG. 2A, the variable resistance 215 (Rᵥₐᵣ) is controlled by a control unit 217′, this time one that outputs a digital control signal (i.e., 3 bits) so as to thereby provide at least three, dynamically selectable resistance settings, R₀, R₁ and R_{N}. In one embodiment, the first digitally selectable resistance setting, R₀, corresponds to data read operations and constitutes a lowest resistance value for Rᵥₐᵣ 215′ so as to thereby couple the common source plane 212′ to ground (or another equivalent reference voltage rail) with minimal resistance approximating a shorted connection to ground (or other).

In the same one or another embodiment, the third resistance setting, R_{N}, corresponds to a flash erase operation and constitutes a highest resistance value for Rᵥₐᵣ 215′ so as to thereby substantially decouple the common source plane 212′ from ground (or another equivalent reference voltage rail) and thus allow the common source plane 212′ to essentially float.

In the same one or another embodiment, the second resistance setting, R₁, corresponds to at least one of a soft-programming and hard-programming operation and constitutes an intermediate resistance value for Rᵥₐᵣ 215′ so as to thereby control the voltage of the common source plane 212′ relative to ground (or to another equivalent reference voltage rail) and to thus limit the amount of current drained from a programming power source (e.g., 250 of FIG. 2D) during the corresponding programming operations. If desired, the value of the second resistance setting, R₁, may be made a function of the number, N of bit lines whose floating gate transistors are being soft-programmed so as to thereby establish a desired source plane voltage Vs sufficient to keep the over-erased other transistors sufficiently turned off so as not to overtax the on-chip charge pump (e.g., 250 of FIG. 2D).

FIG. 2C is a circuit schematic of a Flash-erasable memory sector 203 that includes a variable sector resistance 215″ corresponding for example to the analog variable resistance 215 of FIG. 2A or the digital variable resistance 215′ of FIG. 2B. The different bit lines are respectively denoted as BL1, BL2, BL3 and BL4. In alternate embodiments, there can be many more bit lines per sector and/or many more transistors in each memory column. This is just an illustrative example. More specifically, it is expected that advanced embodiments will have substantially more than a 4 K number of transistors per sector, and perhaps as many as about 0.5 M (i.e., 500,000) or more transistors per sector. FIG. 2C shows the orthogonal coupling of the word lines WL₀ through WL₇ to respective ones of control gate nodes G₁₀-G₄₇ in the illustrated 4×8 sector matrix. FIG. 2C also shows how the respective column source lines 212a, 212b, 212c, 212d may couple to a metal strapping line 212′″. It is within the scope of the disclosure that one or more copies of strapping line 212′″ extend horizontally through the middle of the 4×8 sector matrix (if just one such strapping line 212′″ is used) or through equally spaced apart ⅓ heights of the matrix if two strapping lines are used, and so on, so as to thereby reduce effective resistance of the common source plane.

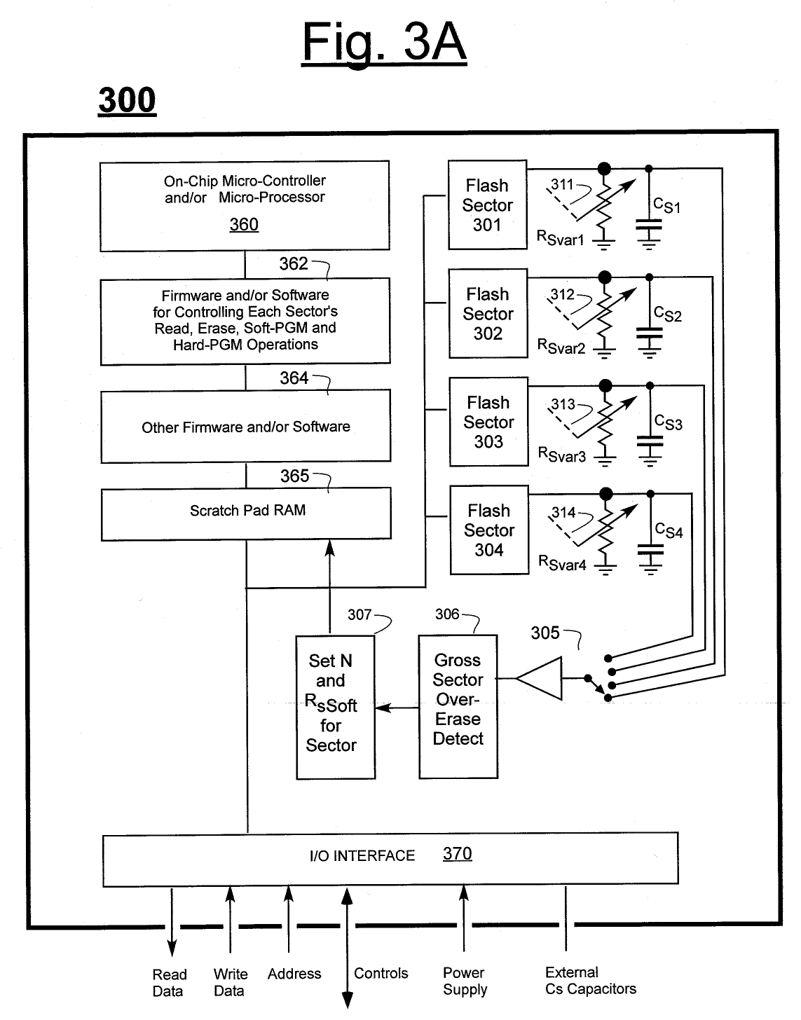

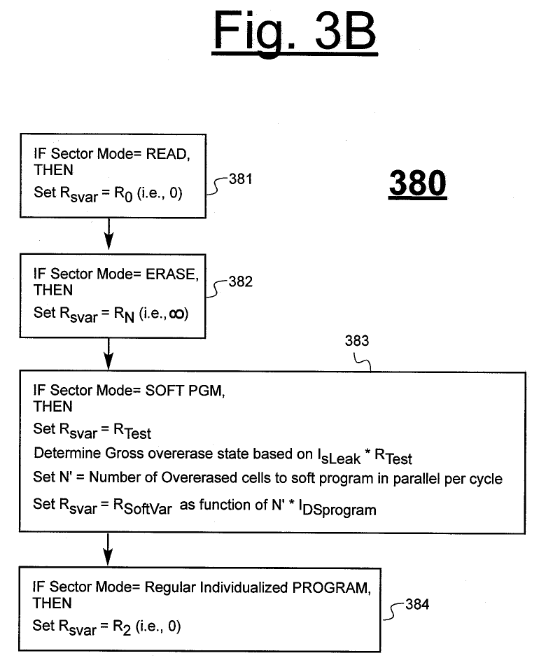

Referring to FIG. 2D, a soft-programming operation in accordance with the disclosure will now be described in detail. Assuming that the over-erasure state of the sector has been determined by testing or it is expected to comport with predefined statistical models, the expected rate of leakage current per turned on bit line (per each bit line 222′ that is selectively coupled to the charge pump 250 and which the pump 250 tries to pump up to say, V_{D}≧+5V) can be determined for the case where variable resistance 215d is set to about zero and/or for the case where variable resistance 215d is incrementally increased through a range of values including an R1 value, where the selectable R1 value of variable resistance 215d is one that will drive Vs sufficiently above ground (or above another chip-wide de-assertion voltage V_{Goff}) for a given number, N of driven-high bit lines 222′ so that over-erased transistors like 248 on those driven-high bit lines are turned off despite their over-erased state when the chip-wide de-assertion voltage V_{Goff} is applied to such over-erased transistors (i.e., 248). Accordingly, one or both of the values for N (number of driven-high bit lines) and R1 are picked either a priori during design or in real time (as will be the case for chip 300 of FIG. 3A) so as to assure that the over-erased transistors (i.e., 248) are safely turned off or have their leakage current (I_{Leak}) sufficiently reduced by virtue of Vₛ being raised sufficiently above V_{Goff} due to the picked values of N and R1. Once the over-erased transistors (i.e., 248) are safely turned off or have their leakage current (I_{Leak}) sufficiently reduced by virtue of Vₛ having been raised sufficiently above V_{Goff}, the on-chip charge pump 250 can easily pump the selected number, N of turned-on bit lines up to the desired HCI drain voltage, say, V_{D}≧+5V so as to thereby assure that transistors like 247 with a V_{Gsoft} voltage of say about +8V applied to their gates will be appropriately soft programmed. Given a dynamically variable source resistance 215d, the value of N can be increased as sector density increases so as to thereby prevent time consumed for soft-programming from becoming excessively large.

Various real time algorithms may be devised for reducing time consumed for soft-programming if Rᵥₐᵣ has a sufficient number of other selectable values (R₂, R₃, R₄, etc.) beyond the minimum three, R₀, R₁ and R_{N}. For example, once a first subset of over-erased transistors have been soft-programmed in a given sector by using the R1 value for Rᵥₐᵣ 215d of FIG. 2D, where the first cycle soft-programming is distributed over a corresponding set of M bit lines (where M>N), the amount of leakage current per bit line will have been reduced in the corresponding set of M bit lines and as a result, the number N of bit lines that are next simultaneously driven high in a second soft-programming cycle can be increased above that used in the first cycle. By progressively increasing N, one can reduce total amount of time spent in soft-programming. Thus a method in accordance with the present disclosure comprises: (a) using a first value of N for soft-programming a first subset of over-erased transistors distributively located on a set of M bit lines (where M is greater than at least the first N); and (b) after the first subset has been soft-programmed, and as a result, current leakage per bit line decreases in the set of M bit lines, using a larger second value of N for soft-programming a second subset of over-erased transistors distributively located on a set of M bit lines, where N is the number of bit lines that are simultaneously activated during each soft-programming session.

Referring to FIG. 3A, shown is a block diagram of a monolithic integrated circuit (IC) chip 300 comprising a plurality of Flash-erasable, nonvolatile memory sectors 301-304, each having a corresponding variable resistance means Rₛᵥₐᵣ₁-Rₛᵥₐᵣ₄ for dynamically controlling the common source state of that respective sector 301-304 during a respective read, erase, soft-programming and hard-programming operation performed on that sector. The illustrated IC 300 includes an on-chip micro-controller and/or microprocessor core 360 that is structured to execute one or more control algorithms for controlling the respective read, erase, soft-programming and hard-programming operations of the on-chip flash sectors 301-304. Alternatively or additionally the illustrated IC 300 includes an on-chip firmware section 362 and/or an on-chip software section 362 operatively coupled to the controller 360 and/or operatively coupled to control terminals 311-314 of the respective variable resistance means Rₛᵥₐᵣ₁-Rₛᵥₐᵣ₄ for dynamically controlling the common source state of respective ones of the sectors 301-304 during respective read, erase, soft-programming and/or hard-programming modes of those sectors. The on-chip firmware and/or software section 362 may be structured to carry out one or more of the above described erase, soft-programming and hard-programming operations on various ones of the flash memory sectors 301-304 at appropriate times as well as mediating the reading of data from operative ones of the sectors in response to read and write commands received via an interface 370 from chip-external sources. The automatically executed operations may include the progressive soft-programming ones described above where the number, N of drive-high bit lines progressively increases as more and more over-erased transistors have their threshold voltages compacted towards the desired nominal value (i.e., Vₜ=+2V).

Aside from managing read and write data signals, address signals and other control signals (i.e. write enable, clock, clock enable, etc.) that are exchanged with external circuitry, the interface 370 may receive external instructing signals that are manufactured for modifying and/or overwriting software and/or firmware code stored in sections 362 and/or 364 for thereby modifying the behavior of device 300 even in some instances where device 300 is installed in an operational circuit in the filed and the new instructing signals are transmitted into interface 370 from a remote instructing or reprogramming center via the internet or another medium of wired or wireless transmission.

Aside from managing reprogramming of sections 362 and/or 364, the interface 370 may receive one or more ground and power signals from external sources. The interface 370 may include means for adding external capacitors (Cs) in parallel with respective on-chip source capacitances Cₓ₁-Cₛ₄ of the respective memory sectors 301-304 if desired. Although FIG. 3A shows just four Flash memory sectors 301-304, it understood that IC 300 may have many more and that various algorithms may be employed for managing data directories and/or transferring data from one older sector to a freshly erased and soft-programmed second sector as commands are received for adding or overwriting old data. In this regard, IC 300 may include additional firmware and/or software sections 364 for managing the I/O interface 370 and/or for managing files stored across the various sectors 301-304. IC 300 may include scratch pad RAM (random access memory) 365 for temporarily storing data and/or ROM sections (not shown, but understood to contain hard-coded machine instructions and/or data that is uneraseable by users after being hard coded in at the factory). Some of the algorithms defined within IC 300 may be contained in overwritable memory sections (i.e., Flash sections), including the soft-programming control algorithms so that such may be updated in the field from time to time if such becomes necessary as indicated above.

The illustrated memory-containing IC 300 additionally contains a software driven selection switch 305 that couples the voltage developed across a selectable one of variable resistance means Rₛᵥₐᵣ₁-Rₛᵥₐᵣ₄ to an analog-to-digital converter (or to other voltage detecting means) so that measurements or detections can be made of how much leakage current respectively flows out of the common source plane of each respective Flash sector 301-304 after that sector has been flash erased but before soft-programming of the sector completes. Gross leakage from a given sector may be determined by commanding a predetermined number (e.g., M′) of the bit lines in that sector to an above ground assertion voltage, i.e., V_{D}=+3V or +5V while driving all the word lines (control gates) of the sector that drive transistors of the M′ bit lines to the nominal V_{Goff} value (i.e., to 0V) and while commanding the variable source resistance R_{svarX} of that sector 30X (where X=1, 2, 3, . . . , 4) to a predefined testing resistance value. The value of M′ may vary from application to application depending for example on the capabilities of the on-chip charge pump (i.e., 250 of FIG. 2D). Since the predefined testing resistance value of R_{svarX} is known and M′ is known, the per-bit-line leakage situation of the tested sector 30X may be surmised from the sampled M′ bit lines and this may give an in-field indication of how over-erased or no that sector is following a given flash erase operation. Module 306 generates a signal representing the degree of over-erasure (i.e., indicating how widespread the post-erase threshold voltages are and how much compaction will be needed). This signal is output to module 307 where the latter may contain a pre-programmed lookup table for determining an appropriate initial value of N for soft-programming the sector 30X and an initial value of R_{svarX} for soft-programming that sector 30X and, optionally; an appropriate initial value of M for progressively soft-programming the sector 30X. (Recall that N is the number of bit lines simultaneously driven high during a soft-programming session and M is a number of bit lines that participate in a progressive escalation of N if such is carried out. M can be equal to or less than the total number of bit lines in a given sector.) The initial values for N, R_{svarX} and optionally, M are supplied to section 362 for use in a subsequent automatic soft-programming of the targeted sector.

Modules 305, 306 and 307 may additionally be used for retesting a given sector 30X (where X=1, 2, 3, . . . , 4) after it has been soft-programmed at least once to thereby determine a next set of N, R_{sSoft} and M (optional) values for that sector 30X so as to more quickly finish the soft-programming operations. The amount of Vₜ shift due to soft-programming may vary as the IC ages and/or with changing environmental conditions. The ability to intelligently switch the values of N, R_{sSoft} and M (optional) in the face of in-field measured conditions allows designers to push the technology closer to its limits and speed us the rate at which soft-programming completes.

Referring to FIG. 3B, shown is a flow chart of a method 380 for managing the variable source resistance means R_{svarX} of a given sector X (where X=1, 2, 3, . . . , 4) depending on the mode of the sector. In step 381 it is determined if the given sector 30X is in READ mode. If Yes, the corresponding R_{svarX} is set to the R0 value (typically substantially close to zero ohms).

In step 382 it is determined if the given sector 30X is in ERASE mode. If Yes, the corresponding R_{svarX} is set to the RN value (typically substantially close to an open circuit).

In step 383 it is determined if the given sector 30X is in a start of soft-programming mode. If Yes, the corresponding R_{svarX} is first set to a predefined testing value (R_{Test}) and the sector is driven into a leakage sampling mode (by driving M′ bit lines high while applying V_{Goff} to all the word lines). More than one value R_{Test} may be used if desired. The measured voltage values from such testing correspond to the product, I_{sLeakage}*R_{Test}. The over-erasure state of the sector 30X may be determined to an appropriate extent from gathering such test data in the field. In response, a lookup table and/or another appropriate algorithm may be used to determine what initial value of N is most suited for soft-programming the sector under its current condition. Once N (the number of bit lines to be simultaneously driven high) is determined, a corresponding value for R_{svarX} may be established for use during the actual soft-programming process. Typically there will be a predefined drain-to-source current value (I_{DSprogram}) per transistor that is associated with the Flash transistor technology for assuring that HCI-based soft-programming occurs as desired. The value of R_{svarX} for the ensuing soft-programming process is then set to a value R_{sSoftVar} corresponding to the product N′*I_{DSprogram} where N′ is the number of transistors being simultaneously soft-programmed in a given cycle and where N′*I_{DSprogram}*R_{sSoftVar} is approximately equal to the offset voltage to be developed across the corresponding R_{svarX} resistance means so as to keep over-erased other transistors turned off.

In step 384 it is determined if the given sector 30X is in Regular PROGRAM mode. If Yes, the corresponding R_{svarX} is set to the R2 value (typically substantially close to zero ohms). This R2 value allows a maximum I_{DS} to flow for thereby quickly initiating HCI programming of the targeted transistor. All the over-erased transistors in the sector have already been soft-programmed and therefore it is not longer necessary to raise Vs above V_{Goff}. However, if desired, the R2 value can be set to one slightly above zero ohms for thereby keeping other transistors (other than the one targeted for regular programming) safely in the off state.

The present disclosure is to be taken as illustrative rather than as limiting the scope, nature, or spirit of the subject matter claimed below. Numerous modifications and variations will become apparent to those skilled in the art after studying the disclosure, including use of equivalent functional and/or structural substitutes for elements described herein, use of equivalent functional couplings for couplings described herein, and/or use of equivalent functional steps for steps described herein. Such insubstantial variations are to be considered within the scope of what is contemplated here. Moreover, if plural examples are given for specific means, or steps, and extrapolation between and/or beyond such given examples is obvious in view of the present disclosure, then the disclosure is to be deemed as effectively disclosing and thus covering at least such extrapolations.

By way of a further example, it is understood that the configuring of a software driven memory IC (e.g., 300 of FIG. 3A) in accordance with the disclosure can include use of an external computer (not shown) to carry out activation of the re-programming function in the software driven memory IC (e.g., 300). A computer-readable medium (e.g., hard disk) or another form of a software product or machine-instructing means (including but not limited to, a compact disk, a flash memory stick, a downloading of manufactured instructing signals over a network, etc.) may be used for instructing an instructable machine (e.g., the external computer) to carry out such reprogramming activities for the software driven memory IC (e.g., 300), where the activities can include selective activation of different soft-programming algorithms and/or changing of values in lookup tables such as the initial N, M and/or R_{varSoft} to be used in accordance with the present disclosure. As such, it is within the scope of the disclosure to have an instructable machine carry out, and/to provide a software product adapted for causing an instructable machine to carry out a machine-implemented method that programs or reprograms a software driven memory IC (e.g., 300) initially in the factory and/or while the software driven memory IC is installed in an operational circuit in the field.

### Reservation of Extra-Patent Rights, Resolution of Conflicts, and Interpretation of Terms

After this disclosure is lawfully published, the owner of the present patent application has no objection to the reproduction by others of textual and graphic materials contained herein provided such reproduction is for the limited purpose of understanding the present disclosure of invention and of thereby promoting the useful arts and sciences. The owner does not however disclaim any other rights that may be lawfully associated with the disclosed materials, including but not limited to, copyrights in any computer program listings or art works or other works provided herein, and to trademark or trade dress rights that may be associated with coined terms or art works provided herein and to other otherwise-protectable subject matter included herein or otherwise derivable herefrom.

If any disclosures are incorporated herein by reference and such incorporated disclosures conflict in part or whole with the present disclosure, then to the extent of conflict, and/or broader disclosure, and/or broader definition of terms, the present disclosure controls. If such incorporated disclosures conflict in part or whole with one another, then to the extent of conflict, the later-dated disclosure controls.

Unless expressly stated otherwise herein, ordinary terms have their corresponding ordinary meanings within the respective contexts of their presentations, and ordinary terms of art have their corresponding regular meanings within the relevant technical arts and within the respective contexts of their presentations herein.

Given the above disclosure of general concepts and specific embodiments, the scope of protection sought is to be defined by the claims appended hereto. The issued claims are not to be taken as limiting Applicant's right to claim disclosed, but not yet literally claimed subject matter by way of one or more further applications including those filed pursuant to 35 U.S.C. §120 and/or 35 U.S.C. §251.

What is claimed is:

1. A NOR-type Flash memory device comprising:
(a) a plurality of floating gate transistors each having a source, a drain, a floating gate and a control gate, where subsets of the transistors define corresponding memory sectors and sources of transistors in a same sector are coupled together to define a common source plane;
(b) a variable resistance coupled between the common source plane of at least one of the sectors and a first reference voltage line; and
(c) a resistance control unit coupled to the variable resistance and operative to switch the variable resistance to at least three substantially different resistance values.

2. The NOR-type Flash memory device of claim 1 wherein said at least three substantially different resistance values include a first resistance value corresponding to a data reading mode of the at least one sector, second resistance value corresponding to a soft-programming mode of the at least one sector and third resistance value corresponding to a flash erase mode of the at least one sector.

3. The NOR-type Flash memory device of claim 2 wherein said control unit is operative to further switch said variable resistance to at least a fourth resistance value that is substantially different from said first through third resistance values.

4. The NOR-type Flash memory device of claim 3 wherein said fourth resistance value corresponds to a leakage test mode that detects a post flash erase leakage current of the at least one sector.

5. The NOR-type Flash memory device of claim 1 wherein said resistance control unit outputs an analog control signal for controlling the variable resistance.

6. The NOR-type Flash memory device of claim 1 wherein said resistance control unit outputs a digital control signal for controlling the variable resistance.

7. The NOR-type Flash memory device of claim 6 wherein said digital signal comprises at least two bits for defining said first through third resistance values.

8. The NOR-type Flash memory device of claim 6 wherein said digital signal comprises at least three bits for defining said first through third resistance values and up to five more different resistance values for the variable resistance.

9. The NOR-type Flash memory device of claim 1 wherein said first reference voltage line is a ground line and the ground voltage (0V) also defines a nominal de-assertion voltage (V_{Goff}) applied to control gates of said floating gate transistors for purpose of turning those transistors off.

10. The NOR-type Flash memory device of claim 2 wherein said soft-programming mode includes applying a soft-programming voltage (V_{Ghi}=V_{Gsoft}) to the control gates of floating gate transistors that are being soft-programmed where the soft-programming voltage is less than a hard-programming voltage (V_{Ghi}=V_{Ghard}) applied to the control gates of floating gate transistors that are being hard-programmed, where soft-programming shifts a local threshold voltage of a transistor that is being soft-programmed towards an intermediate threshold voltage that allows the transistor to be turned off when a nominal de-assertion voltage (V_{Goff}) is applied to the control gate of the soft-programmed transistor and allows the transistor to be turned on when a nominal assertion voltage (V_{Gon}) is applied to the control gate of the soft-programmed transistor, whereas hard-programming shifts a local threshold voltage of a transistor that is being hard-programmed to an above-intermediate threshold voltage that prevents the transistor from being turned on when the nominal assertion voltage (V_{Gon}) is applied to the control gate of the hard-programmed transistor.

11. The NOR-type Flash memory device of claim 1 and further comprising:
(d) an on-chip controller operatively coupled to the resistance control unit and configured for controlling each sector during a respective a flash erase mode of the sector, a data reading mode of the sector, a soft-programming mode of the sector and a flash erase mode of the given sector, wherein:
(d.1) said flash erase mode shifts threshold voltages of all floating gate transistors in the given sector that is undergoing flash erase towards below-nominal values;
(d.2) said data reading mode relies on all readable floating gate transistors in the sector undergoing a read having a local threshold voltage that is at or substantially close to a predefined nominal threshold voltage (V_{tNominal});
(d.3) said soft-programming mode shifts threshold voltages of floating gate transistors in the sector with values substantially below said predefined nominal threshold voltage closer to the nominal threshold voltage (V_{tNominal});
(d.4) said hard-programming mode shifts threshold voltages of one or more selected floating gate transistors in the sector to values substantially above said nominal threshold voltage (V_{tNominal}); and
(d.5) said on-chip controller includes a soft-program defining unit that defines how many (N) bit lines in a given sector will be simultaneously asserted during a given soft-programming session for the given sector and what resistance value (R_{sSoft}) will established by the variable resistance of the given sector during the given soft-programming session.

12. The NOR-type Flash memory device of claim 11 and further comprising:
(e) an on-chip detector operatively coupled to the on-chip controller and configurable for detecting how much current flows through the respective variable resistance of one or more sectors when the one or more sectors each have a respective number M′ of bit lines asserted within and nominal de-assertion voltages applied to control gates of at least all floating gate transistors driven by the M′ asserted bit lines; and
wherein said soft-program defining unit defines how many (N) bit lines in a given sector will be simultaneously asserted during a given soft-programming session as a function of the current detection performed by said on-chip detector.

13. A method comprising:
(a) providing a respective dynamically variable source resistance for each sector in a NOR-type Flash memory device;
(b) setting the variable source resistance of a given sector to a relatively low value (i.e., close to zero) during reading of said sector;
(c) setting the variable source resistance of a given sector to a relatively high impedance value (i.e., close to being an open circuit) during flash erasing of said sector; and
(d) setting the variable source resistance of a given sector to a first intermediate resistance value at least during a first soft-programming session carried out within the given sector, where the first intermediate resistance value is one that raises a common source voltage (V_{S}) of the sector above a nominal turn off voltage (V_{Goff}) and thus drives gate-to-source voltages (V_{GS}) for transistors that have the nominal turn off voltage (V_{Goff}) applied to them into substantially nonconductive modes even where the nominal turn off voltage (V_{Goff}) is applied to over-erased ones of transistors in the sector.

14. The method of claim 13 and further comprising:
(e) setting the variable source resistance of a given sector to a second intermediate resistance value during a testing mode that tests the extent to which the corresponding sector has been over-erased.

15. The method of claim 14 and further comprising:
(f) using results of the testing mode to automatically determine a number N′ of transistors that are to be simultaneously soft-programmed in that sector during a Vt compaction cycle carried out on that sector.

16. The method of claim 15 and further comprising:
(g) using the determined number N′ of transistors that are to be simultaneously soft-programmed for establishing a corresponding resistance value of said variable resistance of the given sector.

17. A method of progressively soft-programming a NOR-type Flash memory device having a plurality of floating gate transistors each having a source, a drain, a floating gate and a control gate, where subsets of the transistors define corresponding memory sectors and sources of transistors in a same sector are coupled together to define a common source plane; and where a variable resistance is coupled between the common source plane of at least one of the sectors and a first reference voltage line, the method comprising:
(a) using a first value, N1 for soft-programming a first subset of over-erased transistors distributively located on a set of M bit lines, where M is greater than at least the first value of N1 and N1 defines how many bit lines will be simultaneously driven to a first soft-programming assertion voltage during a first soft-programming session; and
(b) after the first subset has been soft-programmed, and as a result, current leakage per bit line decreases in the set of M bit lines, using a larger second value, N2>N1 for soft-programming a second subset of over-erased transistors distributively located on a set of M bit lines, where N2 is the number of bit lines that are simultaneously activated to a second soft-programming assertion voltage during the second soft-programming session.

18. A manufactured instructing signal structured to instruct an identified programmable and predefined memory device to carry out a soft-programming operation where the predefined memory device includes a NOR-type Flash memory array having a plurality of floating gate transistors each having a source, a drain, a floating gate and a control gate, where subsets of the transistors define corresponding Flash memory sectors and sources of transistors in a same sector are coupled together to define a common source plane and where at least a first variable resistance is coupled between the common source plane of at least one of the sectors and a first reference voltage line, the manufactured instructing signal being structured so as to:
(a) cause the predefined memory device to use a first value, N1 for soft-programming a first subset of over-erased transistors distributively located on a set of M bit lines, where M is greater than at least the first value of N1 and N1 defines how many bit lines will be simultaneously driven to a first soft-programming assertion voltage during a first soft-programming session; and
(b) cause the predefined memory device to use a first of plural values of selectable resistances for the first variable resistance during said first soft-programming session.

19. The manufactured instructing signal of claim 18 wherein the manufactured instructing signal further structured so as to:
(a.1) cause the predefined memory device to automatically select said first value N1 for the number of bit lines that are to be simultaneously driven to the first soft-programming assertion voltage during a first soft-programming session based on detection of leakage current from a sampling of the M bit lines; and
(b.1) cause the predefined memory device to automatically select said first of plural values of selectable resistances for the first variable resistance based on the first value N1 selected in said step (a.1).
